(19) United States
(12) Patent Application Publication
(10) Pub. No.: US 2008/0063129 A1
(43) Pub. Date: Mar. 13, 2008

(54) System and method for pre-defined wake-up of high speed serial link

(75) Inventor: Martti Voutilainen, Espoo (FI)

Correspondence Address: Fang Geng, Esq.;Nokia Corporation 1-4-737, 6000 Connection Drive, Irving, TX, 75039, US

(73) Assignee: Nokia Corporation

(21) Appl. No.: 11/520,299

(22) Filed: Sep. 11, 2006

(51) Int. Cl. H03D 3/24; H04L 7/00

(52) U.S. Cl. 375/376; 375/354

(57) ABSTRACT

A system and method for transmitting and receiving through a high speed serial link with power up and power down capability. The exemplary embodiments of this invention involves a method of power up and power down the high-speed serial link without using high voltage swing control and signaling. Both the transmitter and the receiver wake up only during pre-defined burst cycles. During each burst cycle, data will be transmitted and received in burst mode. Outside each burst cycle, the transmitter and receiver will be powered off or partially powered off. Various phase-locked loop based circuit ensure the transmitter and the receiver can be locked in frequency and phase quickly at the time of power-up. The duration of the burst cycle and the interval between two adjacent burst cycles can be either fixed or changed by upper level protocol.

### FIELD OF THE INVENTION

The exemplary embodiments of this invention relate generally to data communication. In particular, the exemplary embodiments of this invention relate to transmission of data over a high-speed serial link between two subsystems of a data communication system.

### BACKGROUND OF THE INVENTION

This section is intended to provide a background or context to the exemplary embodiments of this invention. The description herein may include concepts that could be pursued, but are not necessarily ones that have been previously conceived or pursued. Therefore, unless otherwise indicated herein, what is described in this section is not prior art to the description and claims in this application and is not admitted to be prior art by inclusion in this section.

A high-speed serial transfer interface such as Low Voltage Differential Signaling (LVDS) has attracted attention as an interface standard aiming at reducing Electro Magnetic Interference (EMI), thermal and other noise. In the high-speed serial transfer interface, data transfer is realized by allowing a transmitter circuit to transmit serialized data using differential signals and a receiver circuit to differentially amplify the differential signals. For example, the Mobile Industry Processor Interface (MIPI) has defined a source-synchronous, high-speed, low-power physical layer specification D-PHY (available from MIPI website). This D-PHY specification has been written primarily for the connection of camera and display applications to a host processor. Nevertheless, it can be applied to many other applications. MIPI envisioned that the D-PHY specification will be used in a dual-simplex configuration for interconnections in a more generic communication network.

U.S. Patent Publication No. 2003/0198296, entitled, “Serial Data Link With Automatic Power Down,” describes a method of powering down a serial data link, by setting the differential signals from the transmitter cell to an illegal state and upon detecting the illegal state, powering off the receiver circuit. However, this approach requires additional circuit and logic at the transmitter to set differential signal to an illegal state and at the receiver side to detect the illegal stage from the differential line.

For high-speed serial transfer interface, a phase-locked loop (PLL) is often used as a clock synthesizer and frequency synchronization circuit. A PLL, which typically includes a phase detector, a charge pump, a loop filter, and a Voltage Controlled Oscillator (VCO), may be used to generate clock signals. A PLL typically multiplies up the frequency of the lower frequency timing reference in a ratio that is defined by forward and feedback divides. A PLL can also be used in data and clock recovery in phase tracking for data being transmitted. A phase detector compares the lead or lag of phases between a VCO clock and the input data. The comparison result is filtered by a loop filter for filtering out high frequency noise and data jitter that can adversely affect the stability of the VCO clock. The loop filter output a control voltage for the VCO for aligning the rising edges of the input data. When the PLL is locked, the data can be extracted from the phase detector accordingly. However, for a PLL based clock recovery to work in the high-speed serial transfer interface, a data stream needs to transition frequently enough to correct any drift in the PLL's oscillator. The limit for how long a clock recovery unit can operate without a transition is known as its maximum consecutive identical digits (CID) specification. To insure frequent transitions, some sort of encoding is used; 8B/10B encoding is very common, and Manchester encoding, which is used in old revisions of local area network protocols such as IEEE 802.3, is another encoding method that serves the same purpose.

The high-speed serial transfer interface in mobile terminals requires high power efficiency and near zero idle power consumption. However, since the high-speed serial transfer interface allows current to constantly flow through the transmitter circuit and the receiver circuit, reducing power consumption is typically only possible by sending information in burst mode and switching off the link after every data transmission. One way to implement power up and power down of the high-speed serial link is to use separate control and signaling in addition to the high-speed serial link. FIG. 1 shows a high-speed differential link 110, connected to high speed transmitter 120, high speed receiver 130, control/signaling for transmitter 140, control/signaling for receiver 150 and link control logic 160. Typically, high voltage swing (for example 1.2V CMOS) links are used to handle the control and signaling of power up and power down.

The use of such high voltage swing links creates several problems. For example, in order for the output current to be small enough to make EMI acceptable in low-cost connectors, output current and current slew rate has to be limited to low values. This limits maximum interconnection cable length to about 12 inches (30 cm) and maximum bit rate to around 20 Mbps. Further, the high voltage swing link approach becomes difficult or impossible to implement when the high-speed signal is transmitted over optical fiber where there are no separate links to provide power up and power down control and signaling.

Accordingly, there is a need to define a new method that can be used to implement burst mode operation without using a high voltage swing link.

### SUMMARY OF THE INVENTION

Various exemplary embodiments of the invention provide apparatus and method for transmitting and receiving through a high speed serial link with power up and power down capability.

In accordance with an exemplary embodiment of this invention there is provided a method to transmit data to a receiver. The method includes generating a clock signal using a phase-locked loop based clock synthesizer; using the clock signal when serializing parallel data into a serial bit stream; transmitting the serialized data only during pre-defined burst cycles; and powering off at least a portion of the phase-lock loop based clock synthesizer outside the pre-defined burst cycles.

Further in accordance with an exemplary embodiment of this invention there is provided a method to receive data from a serial link. This method includes, and only during pre-defined burst cycles, recovering a clock signal from a serial data input using a phase-locked loop based clock recovery circuit; sampling the serial data input using the recovered clock signal; converting the sampled serial data to parallel data; and powering off at least a portion of the phase-locked loop based clock recovery circuit outside the pre-defined burst cycles.

Further in accordance with an exemplary embodiment of this invention there is provided an apparatus to transmit data to a receiving device, which comprises: a phase-locked loop based clock synthesizer to generate clock signal; a serializer to convert parallel data to serialized data; a transmitter to transmit the serialized data only during pre-defined burst cycles; and a switch to power off at least a portion of the phase-locked loop based clock synthesizer outside the pre-defined burst cycles.

Further in accordance with an exemplary embodiment of this invention there is provided an apparatus for receiving data from a serial link, which comprises: a phase-locked loop based clock recovery circuit for recovering a clock signal from a serial data input; a sampling circuit for sampling the serial data received at the input using the recovered clock signal; a deserializer for converting the sampled serial data to paralleled data; and a switch to power off at least a portion of the phase-locked loop based clock recovery circuit outside the pre-defined burst cycles.

Further in accordance with an exemplary embodiment of this invention there is provided a device, which comprises: a first component and a second component; a serial link connecting the first component and the second component; wherein the first component transmits data to the second component only during pre-defined burst cycles.

Further in accordance with an exemplary embodiment of this invention there is provided a device, which comprises: a first component and a second component; a serial link connecting the first component and the second component; a transmitter configured to transmit serial data from the first component only during pre-defined burst cycles; a phase-locked loop based clock recovery circuit for recovering a clock signal from the serial link; a sampling circuit for sampling the serial data input using the recovered clock signal; a deserializer for converting the sampled serial data to paralleled data; means for powering off at least a portion of the phase-locked loop based circuit; and means for locking the phase and frequency of the phase-locked loop to that of the received data. In a specific embodiment, the means for powering off at least a portion of the phase-locked loop based circuit includes a clock gating switch, and the means for locking the phase and frequency includes a combination delayed locking loop DLL and phase locking loop PLL. Each of these specific embodiments are detailed below.

Further in accordance with an exemplary embodiment of this invention there is provided a chipset, which comprises: a phase-locked loop based clock synthesizer circuit to generate a clock signal; a serializer circuit to convert parallel data to a serial bit stream; a transmitter circuit to transmit the serialized data only during pre-defined burst cycles; a switch to power off at least a portion of the phase-locked loop based clock synthesizer outside the pre-defined burst cycles; a phase-locked loop based clock recovery circuit to recover a clock signal from a serial data input; a sampling circuit to sample the serial data input using the recovered clock signal; a deserializer circuit to convert the sampled serial data to paralleled data; and a switch to power off at least a portion of the phase-locked loop based clock recovery circuit outside the pre-defined burst cycles.

### BRIEF DESCRIPTION OF THE DRAWINGS

These and other advantages and features of the invention, together with the organization and manner of operation thereof, will become apparent from the following detailed description when taken in conjunction with the accompanying drawings, wherein like elements have like numerals throughout the several drawings described below.

FIG. 1 shows a block diagram of a high-speed serial link with separate control and signaling for power up and power down

FIG. 2 shows the block diagram of the high-speed serial interface without separate control and signaling for power up and power down;

FIG. 3 shows the block diagram of a two-loop PLL for generating a clock signal in the transmitter;

FIG. 4 shows the block diagram of a two-loop PLL for clock recovery in the receiver;

FIG. 5 shows the block diagram of a single loop PLL for generating a clock signal in the transmitter;

FIG. 6 shows the block diagram of a single loop PLL for clock recovery in the receiver;

FIG. 7 shows the transmitter and receiver wake-up time and duration;

FIG. 8 a perspective view of a mobile phone for which the exemplary embodiments of this invention can be used;

FIG. 9 shows a schematic representation of the circuit of the mobile phone in FIG. 8; and

FIG. 10 shows an overview diagram of a system within which the exemplary embodiments of this invention may be implemented;

### DETAILED DESCRIPTION OF THE VARIOUS EMBODIMENTS

Various exemplary embodiments of this invention describe method and apparatus for transmitting and receiving data through a high-speed, low-power serial interface. The high-speed serial interface can achieve power saving by power up and power down operations without using high voltage swing control signaling.

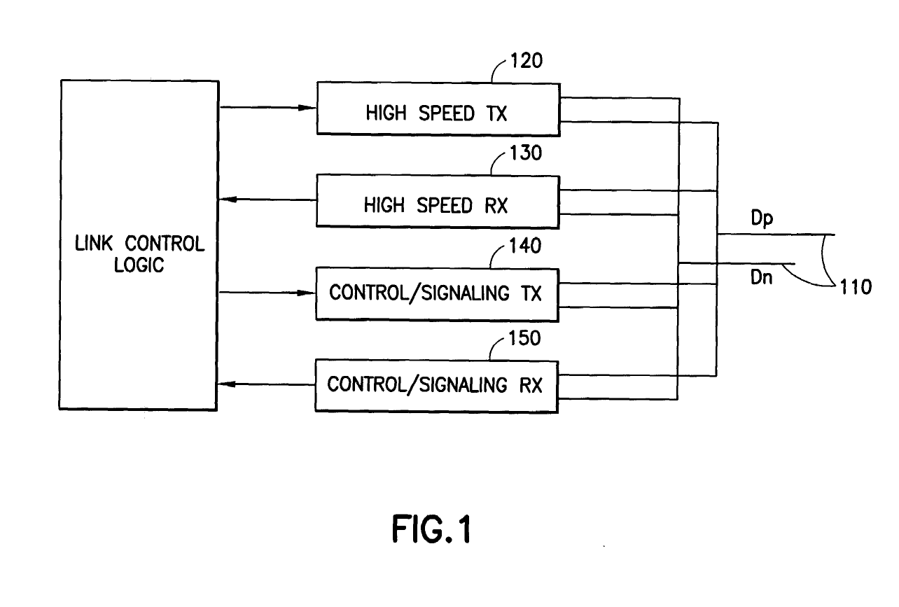

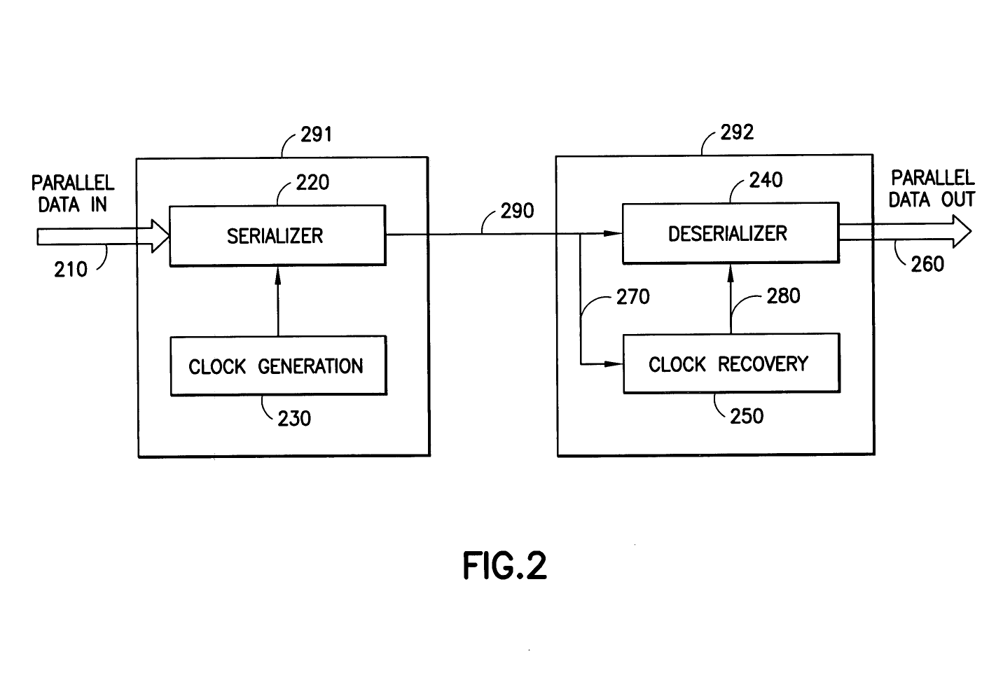

FIG. 2 shows a block diagram of the serial interface which includes a transmitter 291, a channel 290, and a receiver 292. Parallel data input 210, typically 8, 16 or 32 bits wide, applies data to a serializer 220. A PLL based clock generation circuit 230 is utilized to provide a high speed clock signal for the serializer 220. The serialized data may be encoded into 8B10B format (8B10B encoder is not shown in FIG. 1) to help clock recovery, reduce inter-symbol interference generated timing jitter and provide error detection. The serialized data is then transmitted through the channel 290, typically differential pair cable or optical fiber. The serialized data from channel 290 reaches receiver 292 and are sent both to clock recovery 250 and deserializer 240. Clock recovery 250 is a PLL based circuit to recover clock signal from the serialized data. The recovered the clock signal 280 is used by the deserializer 240 to convert the serialized data to parallel data at output 260. If 8B10B is used at the transmitter side, the output will go through 8B10B decoder before the data is used by other part of the system.

To achieve the goal of power efficiency, both the transmitter 291 and the receiver 292 wake up only during pre-defined burst cycles. During each burst cycle, data are transmitted and received in burst mode. Outside each burst cycle, the transmitter 291 and receiver 292 are powered off or partially powered off. Various phase-locked loop based circuit ensure the transmitter 291 and the receiver 292 can be locked in frequency and phase quickly at the time of power-up. The duration of the burst cycle and the interval between two adjacent burst cycles can be fixed or variable, and may be changed by upper level protocol.

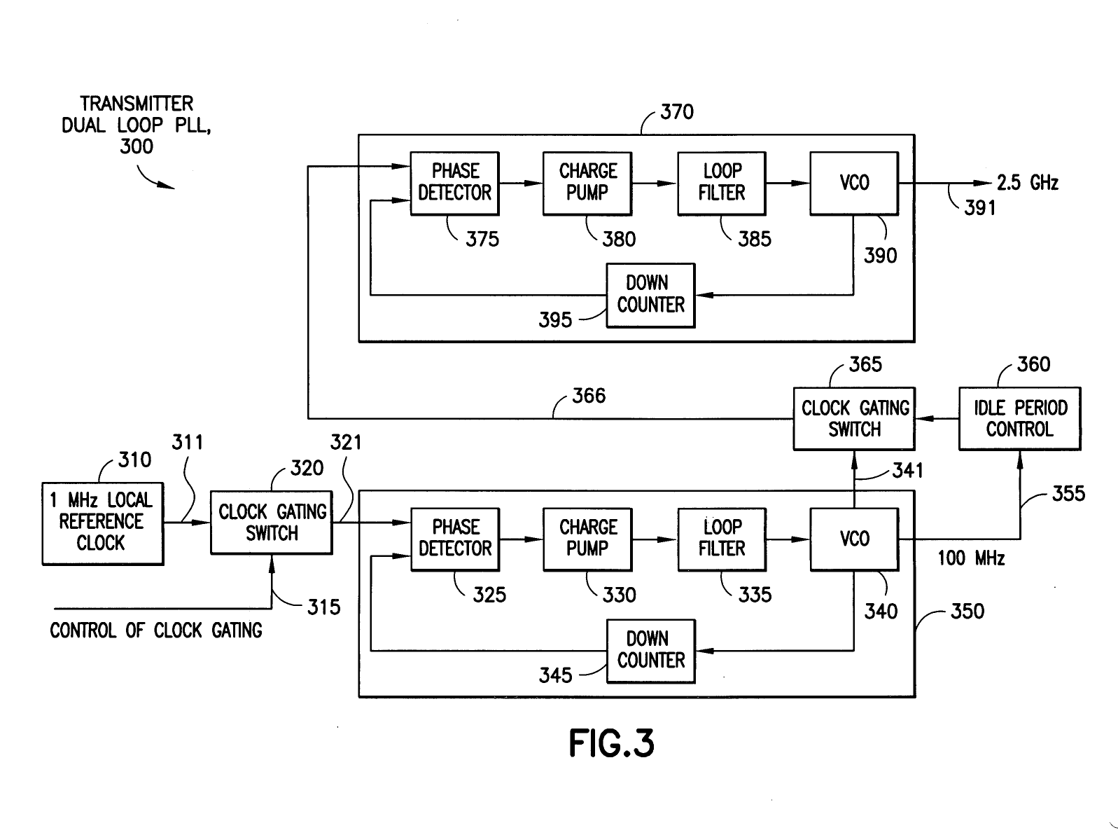

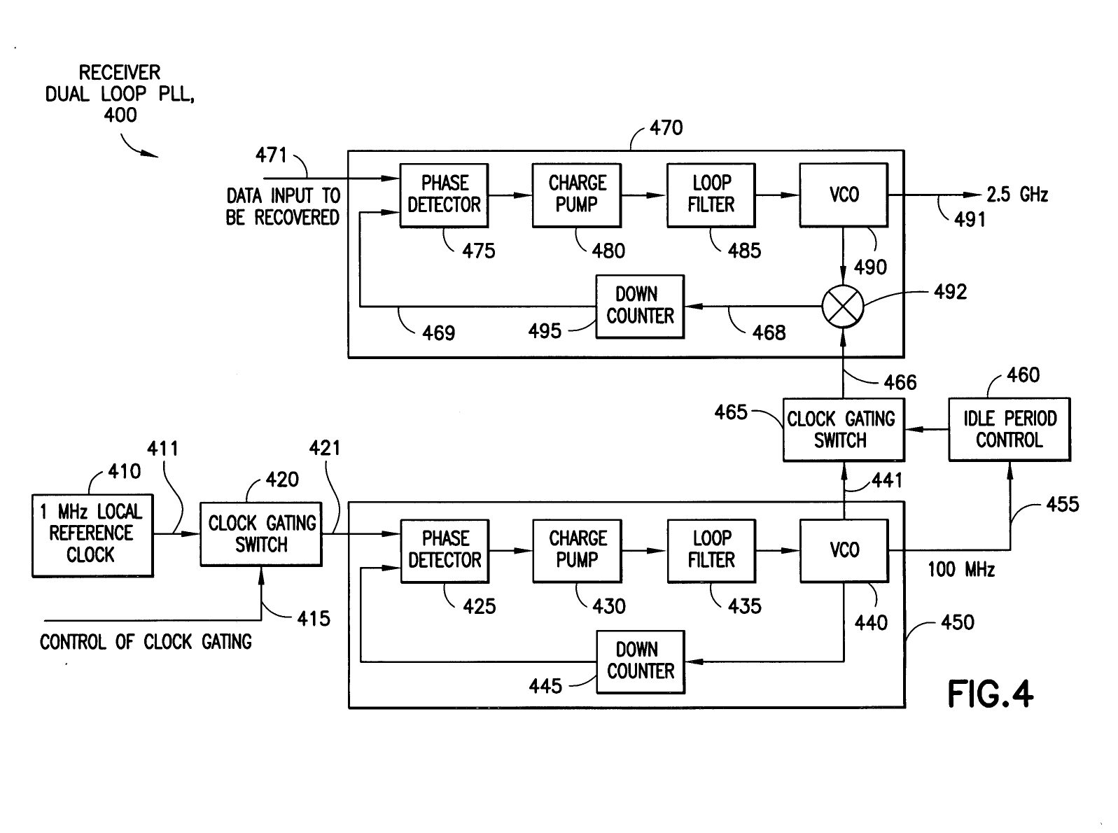

In one exemplary embodiments of the invention, low-frequency (for example 100 KHz-1 MHz) accurate reference oscillators are always running at both the transmitter 291 and the receiver 292. Dual loop PLLs 300, 400 are utilized to generate the clock signal for the transmitter 291 and to provide the recovered clock for the receiver 292. These PLLs are shown in FIGS. 3 and 4, and are described below. The low-frequency loop may always be running, but the driver (electrical or optical in case of optical fiber link as the channel 290) and receiver 292 are turned on only during the data transmission burst cycles. The high frequency PLL loop is also switched on only after pre-defined data transmission burst cycles. In this way, the high frequency PLL in the transmitter 291 and the receiver 292 can be up simultaneously at a pre-defined frequency, and the phase of the high frequency PLL loop may be almost locked assuming that operating conditions, such as temperature do not change very much during the interval between two adjacent burst cycles. It is also possible to power off the low-frequency loop when not sending or receiving in a very long time (for example, longer than 1 ms). The wake-up of the low-frequency loop can be done by a squelch method, which can be implemented even if the channel 290 is optical fiber. The squelch method is used to wake up a link by sending a large amplitude slow single-ended signal from the transmitter 291 to the receiver 292 in one or both wires of the differential channel 290 to inform the receiver 291 to wake up.

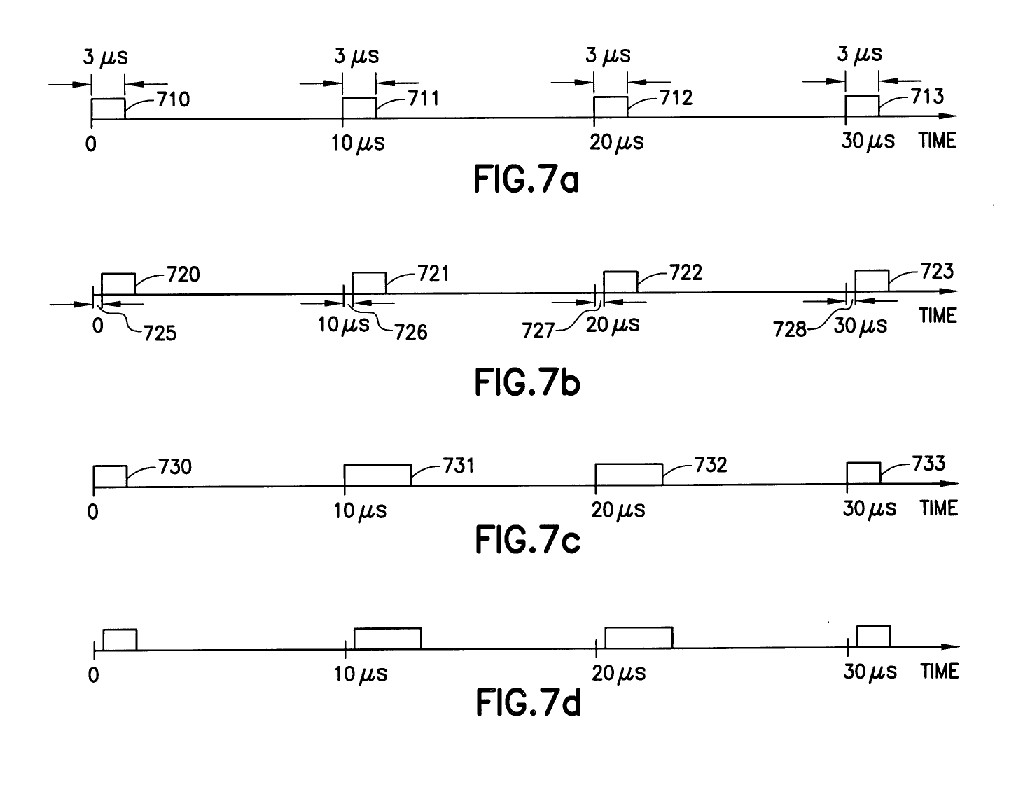

FIG. 3 shows the diagram for the dual loop PLL 300 in the transmitter 291. The low-frequency loop PLL 350, composed of a phase detector 325, a charge pump 330, a loop filter 335, a VCO 340 and a down counter 345, is always running, as long as the interval between two transmitting activities is shorter than a pre-defined value, for example 1 ms. It is also possible to power off low-frequency loop 350, and control of clock gating signal 315 can be used to switch off clock gating switch 320. The local reference clock 310 is an accurate reference oscillator that is always running. It provides a low frequency (for example 1 MHz) reference clock 311, through clock gating switch 320, to the low-frequency loop 350 as input signal 321. As an example, using the values shown in FIG. 3, when the down counter 345 is a divide by 100, the output of the low-frequency loop 350 generates a 100 MHz signal 355 at the output of VCO 340. The high-frequency loop 370 is composed of a phase detector 375, a charge pump 380, a loop filter 385, a VCO 390 and a down counter 395. When a clock gating switch 365 is on, the 100 MHz VCO output 341 of the low-frequency loop 350 passes the clock gating switch 365 and becomes input 366 to the phase detector 375. When the down counter 395 is a divide by 25, the output 391 is a 2.5 GHz clock signal. The VCO output 391 is used by the serializer 220 to convert the parallel data to serial data bits and drive the data bits in serial form to the interconnecting channel 290. The high-frequency loop 370 is switched on only during pre-defined data transmission burst cycles, for example, so as to wake up for 3 μs every 10 μs (example shown in FIG. 7a). Outside the burst cycles, it is switched off to save power. One non-limiting way to implement this is to use an idle period control 360, which takes the 100 MHz output 355 as input. As an example, using the values shown in FIG. 3, for every 1000 clock cycles (which is 10 μs) the idle period control 360 turns on the clock gating switch 365. There may be other control signals (not shown in FIG. 3) connecting the idle period control 360 and the high-frequency loop 370, in order to power on and power off the high-frequency loop 370.

FIG. 4 shows the diagram for the dual loop PLL 400 in the receiver 292. A low-frequency loop PLL 450, composed of a phase detector 425, a charge pump 430, a loop filter 435, a VCO 440 and a down counter 445, is always running, as long as the interval between two receiving activities is shorter than a pre-defined value, for example 1 ms. It is also possible to power off low-frequency loop 450, and control of clock gating 415 can be used to switch off clock gating switch 420. The wake-up of the low-frequency PLL loop 450 can be done by the squelch method, as discussed above. The local reference clock 410 is an accurate reference oscillator that is always running. It provides a low-frequency (for example 1 MHz) reference clock 411, through clock gating switch 420, to the low-frequency loop 450 as input signal 421. As an example, using the values shown in FIG. 4, when the down counter 445 is a divide by 100, the output of the low-frequency loop 450 generates a 100 MHz signal 455 at the output of VCO 440. The high-frequency loop 470 is composed of a phase detector 475, a charge pump 480, a loop filter 485, a VCO 490, a frequency mixer 492 and a down counter 495. The purpose of the frequency mixer 491 is to increase the bandwidth of the PLL 400 so that fast locking may be achieved. When a clock gating switch 465 is on, the 100 MHz VCO output 441 of the low-frequency loop 450 passes the clock gating switch 465 and is mixed with VCO output 467 of the high-frequency loop 470 at frequency mixer 492. An output signal 468 of the frequency mixer 492 is then connected to the down counter 495 and becomes a feedback input 469 to the phase detector 475. As an example, using the values shown in FIG. 4, assuming the data input 471 is at 2.5 GHz, when the down counter 495 is a divide by 1, the VCO output 491 is a 2.5 GHz clock signal. The VCO output 491 is used to sample the input data 471 and also drive the deserializer 240. The high-frequency loop 470 is switched on only during pre-defined data transmission burst cycles, for example, so as to wake up for 3 μs every 10 μs (example shown in FIG. 7b). Outside the burst cycles, it is switched off to save power. One non-limiting way to implement this is to use an idle period control 460, which takes the 100 MHz output 455 as input. As an example, using the values shown in FIG. 4, for every 1000 clock cycles (which is 10 μs) the idle period control 460 turns on the clock gating switch 465. There may be other control signals (not shown in FIG. 4) connecting the idle period control 460 and the high-frequency loop 470, in order to power on and power off the high-frequency loop 470.

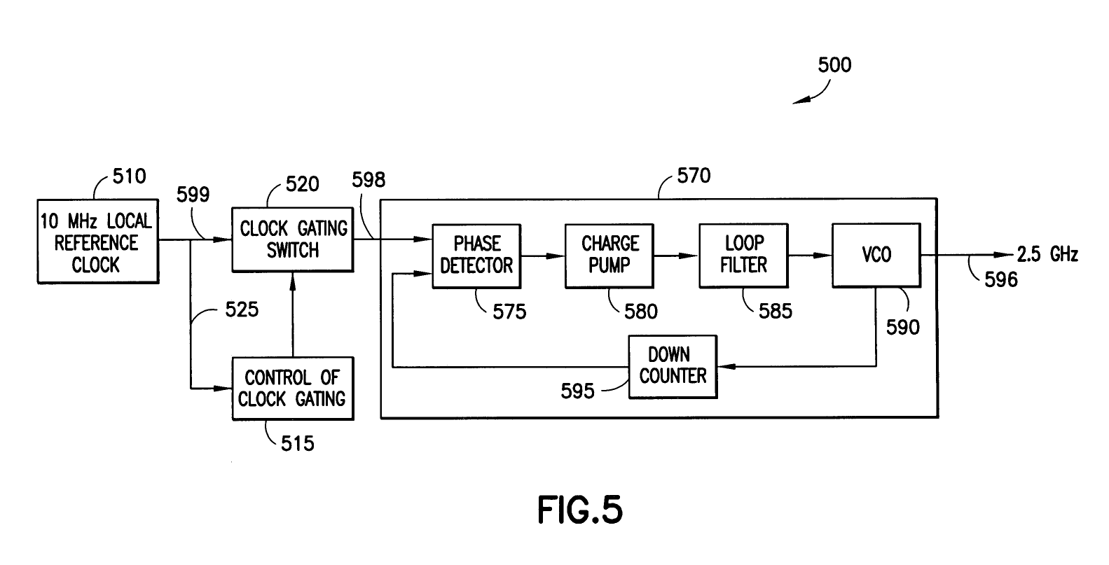

In another exemplary embodiment of the invention, single loop PLLs 500, 600 are used in the transmitter 291 and receiver 292, respectively. FIG. 5 shows the diagram for the single loop PLL 500 in the transmitter 291. The single loop PLL 500 includes circuit 570 composed of a phase detector 575, a charge pump 580, a loop filter 585, a VCO 590 and a down counter 595. The local reference clock 510 is an accurate reference oscillator that is always running. It provides a low frequency (for example 10 MHz) reference clock 599, through clock gating switch 520, to the single loop PLL 570 as input signal 598. As an example, using the values shown in FIG. 5, when the down counter 595 is a divide by 250, the output of the single loop PLL 550 generates a 2.5 GHz signal 596 at VCO output 590. The VCO output 590 is used by the serializer 220 to convert the parallel data to serial data bits and drive the data bits in serial form to the channel 290. The single loop PLL 500 is switched on only during pre-defined data transmission burst cycles, for example, so as to wake-up for 3 μs every 10 μs. Outside the burst cycles, it is switched off to save power. One non-limiting way to implement this is to use a clock gating control 515, which takes 10 MHz output 525 as input. As an example, using the values shown in FIG. 5, for every 100 clock cycles (which is 10 μs) the clock gating control 515 turns on the clock gating switch 520. There may be other control signals (not shown in FIG. 5) connecting the clock gating control 520 and the single loop PLL 570, in order to power on and power off the single loop PLL 500.

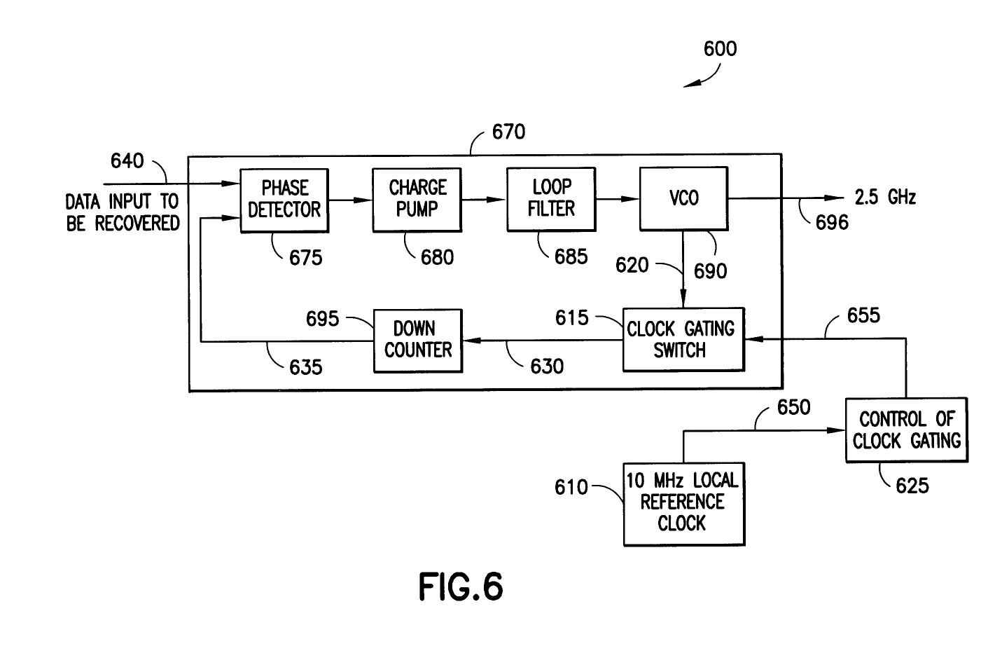

FIG. 6 shows the diagram for the single loop PLL 600 in the receiver 292. The single loop PLL 600 includes circuit 670 composed of a phase detector 675, a charge pump 680, a loop filter 685, a VCO 690 and a down counter 695. The local reference clock 610 is an accurate reference oscillator that is always running. It provides a low frequency (for example 10 MHz) reference clock 615 to clock gating control 625. As an example, using the values shown in FIG. 6, assuming data input 671 is at 2.5 GHz, when the down counter 695 is a divide by 1, the VCO output 691 is a 2.5 GHz clock signal. The VCO output 691 is used to sample input data 691 and also drive the deserializer 240. The single loop PLL 600 is switched on only during pre-defined data transmission burst cycles, for example, so as to wake up for 3 μs every 10 μs. Outside the burst cycles, it is switched off to save power. One non-limiting way to implement this is to use a clock gating control 625, which takes 10 MHz output 615 as input. As an example, using the values shown in FIG. 6, for every 100 clock cycles (which is 10 μs) clock gating control 625 turns on the clock gating switch 615. Once the clock gating switch 615 is on, the output 620 from VCO 690 is connected to the down counter 695. The output 635 of the down counter 695 is then connected to phase detector 675 as feedback input. There may be other control signals (not shown in FIG. 6) connecting the clock gating control 625 and the single loop PLL 670, in order to power on and power off the single loop PLL 600.

Other alternative embodiments of the invention may also be used. In one exemplary alternative embodiment, fast locking is achieved by using a combined Delayed Locked Loop (DLL) for coarse tuning and a PLL for fine tuning of phase. In yet another exemplary embodiment of the invention, fast locking is achieved by a first loop that locks the VCO to an external low frequency reference clock; after that, this loop is switched off and the second loop is activated to lock the VCO to the phase of the input data.

In the various exemplary embodiments of the invention described above, both the transmitter 291 and the receiver 292 only wake up during a pre-defined burst cycle. For example, FIG. 7a shows 4 burst cycles 710, 711, 712 and 713 at the transmitter side and FIG. 7b shows 4 burst cycles 720, 721, 722 and 723 at the receiver side. As an example, in FIG. 7a, the transmitter 291 only wakes up every 10 μs, and each time the link wakes-up for the same duration of time (for example, 3 μs as shown in FIG. 7a) during which a burst of data will be transmitted. In FIG. 7b, the receiver 292 wakes up every pre-defined time that is set to be the same as in the transmitter 291 in FIG. 7a. At the beginning of each burst, special synchronization characters are sent to synchronize idle period control (for example, 360 in FIG. 3). All timing is based on these timing characters sent in previous packet. Both transmitter 291 and receiver 292 are specified so that both are ready for transmission after some known wake-up period, such as 1 μs. After this period the transmitter 291 starts to send synchronization characters (for example 010101010) to lock the receiver phase, and at least one control character (for example K28.5) to lock the receiver byte boundary to be the same as in the transmitter. Typically in about 2 μs (this is part of the burst cycle shown in FIGS. 7a and 7b) both the transmitter 291 and the receiver 292 are up and locked to the same phase of data sent by the transmitter 291, and also the byte boundaries are found. FIG. 7b also shows four delays 725, 726, 727 and 728. These delays are due to transmission time on the channel 290. They are typically very small and uniform in length, although some small jitter is allowed.

FIGS. 7c and 7d show scenarios that are similar to FIGS. 7a and 7b except that the duration of the burst cycles are not fixed. As shown in FIG. 7c, the four burst cycles 730, 731, 732 and 733 at the transmitter side have different durations of time. One non-limiting way to implement this is to cause each burst cycle to include an indicator which indicates the length of the idle period immediately after the burst cycle, calculated from the synchronization characters at the beginning of the burst cycle (length of the burst cycle is taken into account so that next packet does not start too early). An alternative way to implement this is each burst cycle includes special characters which the receiver 292 interprets as an end of payload data and can turn off the power for this burst cycle. In both implementations, the upper level protocol may need to be aware of the minimum and maximum limits arising from physical limitations of the PLL and oscillator start-up and lock times.

The interval between two adjacent burst cycles can also be either fixed or changed by upper level protocol. The upper level protocol ensures that both the transmitter 291 and the receiver 292 use the same interval between two adjacent burst cycles before starting to send and receive data.

When the exemplary embodiments of this invention are used as a dual-simplex link, the upper level protocols can have an acknowledge message sent from receiver 292 to the transmitter 291 through a return channel that may be identical to the transmit channel. The transmitter 291 sends the special control sequence to make locking fast until it gets a message back that the receiver 292 has locked to the incoming data. Only after the lock-in message is received will the payload data be sent. Alternatively, it is also possible to make the locking-sequence long enough that locking is guaranteed. But if an error occurs during the transmission (for example, the receiver 291 is not powered up when it should be), the upper level protocol can detect that the message has not gone through because of a missing acknowledgement.

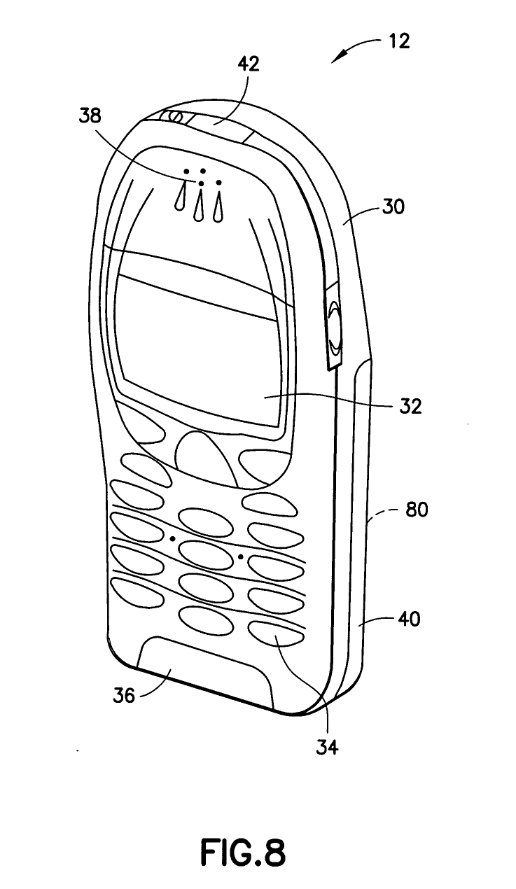

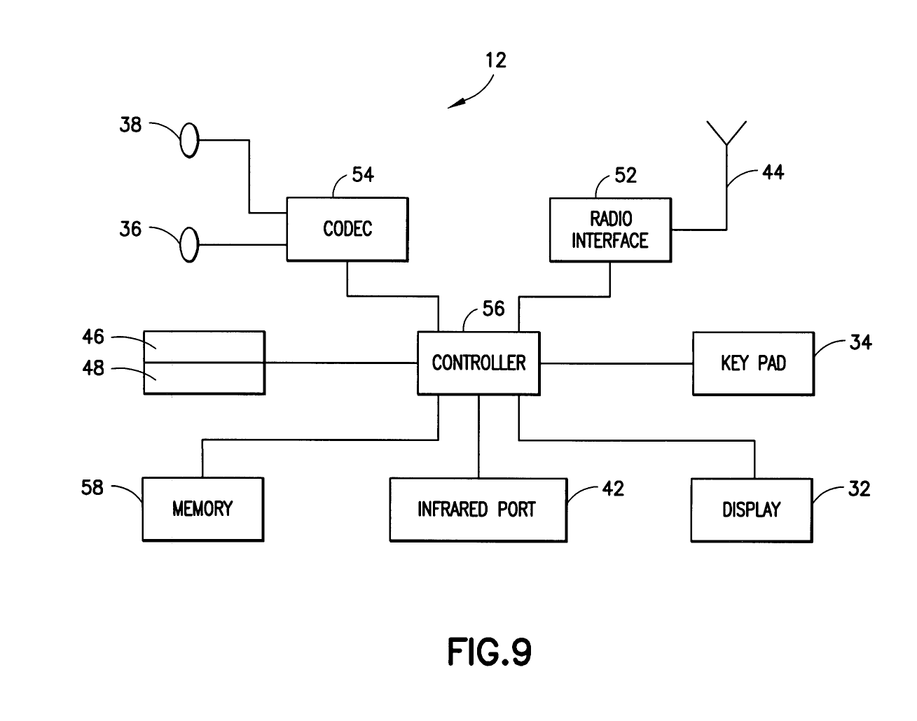

FIGS. 8 and 9 show one representative mobile telephone 12 within which the exemplary embodiments of this invention may be implemented. It should be understood, however, that the exemplary embodiments of this invention are not intended to be limited to one particular type of mobile telephone 12 or other electronic device. The mobile telephone 12 of FIGS. 8 and 9 is composed of various components that may include: a housing 30, a display 32, such as one in the form of a liquid crystal display, a keypad 34, a microphone 36, an ear-piece 38, a battery 40, an infrared port 42, an antenna 44, a smart card 46, a card reader 48, radio interface circuit 52, codec circuit 54, a controller 56 and a memory 58. These individual circuits and elements may all be of a type well known in the art. The high-speed serial interface discussed above with reference to FIGS. 2-7 can be used to implement the communication between any two components in FIG. 9, for example, between the controller 56 and display 32; between the controller 56 and codec 54 or between the codec 54 and the radio interface 52.

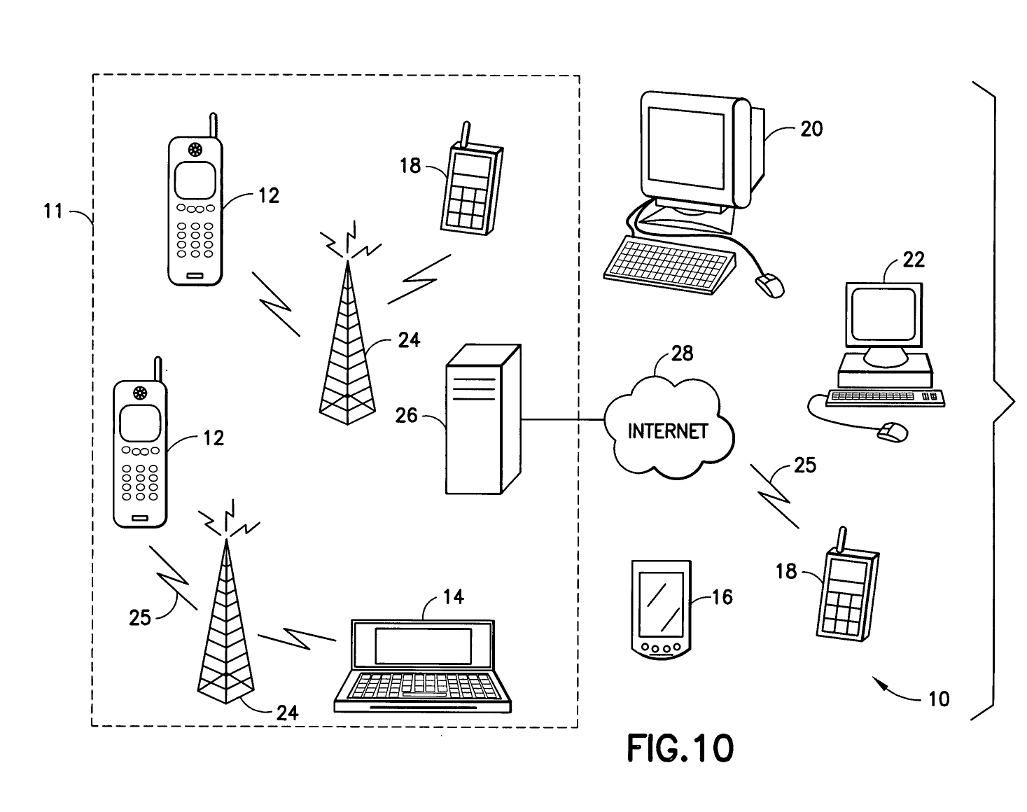

FIG. 10 shows a system 10 in which the exemplary embodiments of this invention can be utilized, comprising multiple communication devices that can communicate through a network. The system 10 may comprise any combination of wired or wireless networks including, but not limited to, a mobile telephone network, a wireless Local Area Network (LAN), a Bluetooth personal area network, an Ethernet LAN, a token ring LAN, a wide area network, the Internet, etc. The system 10 may include both wired and wireless communication devices.

For exemplification, the system 10 shown in FIG. 10 includes a mobile telephone network 11 and the Internet 28. Connectivity to the Internet 28 may include, but is not limited to, long range wireless connections, short range wireless connections, and various wired connections including, but not limited to, telephone lines, cable lines, power lines, and the like.

The exemplary communication devices of the system 10 may include, but are not limited to, the mobile telephone 12, a combination PDA and mobile telephone 14, a PDA 16, an integrated messaging device (IMD) 18, a desktop computer 20, and a notebook computer 22. The communication devices may be stationary or mobile as when carried by an individual who is moving. The communication devices may also be located in a mode of transportation including, but not limited to, an automobile, a truck, a taxi, a bus, a boat, an airplane, a bicycle, a motorcycle, etc. Some or all of the communication devices may send and receive calls and messages and communicate with service providers through a wireless connection 25 to a base station 24. The base station 24 may be connected to a network server 26 that allows communication between the mobile telephone network II and the Internet 28. The system 10 may include additional communication devices and communication devices of different types.

The exemplary embodiments of this invention, as a physical layer high-speed serial link, can be used to implement the communication between any two devices in FIG. 10, for example, between a mobile telephone 12 and a desktop computer 20 or between a mobile telephone 12 and a base station 24. The communication device may communicate using various media including, but not limited to, radio, infrared, laser, cable connection, and the like. That is, the channel 290 may be a wired or a wireless channel.

The foregoing description of embodiments of the exemplary embodiments of this invention have been presented for purposes of illustration and description. It is not intended to be exhaustive or to limit the exemplary embodiments of this invention to the precise form disclosed, and modifications and variations are possible in light of the above teachings or may be acquired from practice of the exemplary embodiments of this invention. The embodiments were chosen and described in order to explain the principles of the exemplary embodiments of this invention and its practical application to enable one skilled in the art to utilize the exemplary embodiments of this invention and with various modifications as are suited to the particular use contemplated.

What is claimed is:

1. A method to transmit data to a receiver, comprising:
generating a clock signal using a phase-locked loop based clock synthesizer;
using the clock signal when serializing parallel data into a serial bit stream;
transmitting the serialized data only during pre-defined burst cycles; and
powering off at least a portion of the phase-look loop based clock synthesizer outside the pre-defined burst cycles.

2. The method of claim 1, wherein a length of an interval between two adjacent burst cycles is variable.

3. The method of claim 1, wherein a duration of each burst cycle is a pre-defined fixed value.

4. The method of claim 1, wherein a duration of each burst cycle can be changed based on the size of payload data.

5. The method of claim 1, further comprising
sending synchronization characters at the beginning of a burst cycle to lock the receiver phase and a byte boundary before sending payload data.

6. The method of claim 1, wherein the phase-locked loop comprises two loops running at different frequencies, with a low frequency loop always running and a high frequency loop running only during the pre-defined burst cycles.

7. The method of claim 1, wherein the phase-locked loop comprises a single loop which is only powered up during the pre-defined burst cycles.

8. A method to receive data from a serial link, comprising:
only during pre-defined burst cycles,
recovering a clock signal from a serial data input using a phase-locked loop based clock recovery circuit;
sampling the serial data input using the recovered clock signal;
converting the sampled serial data to parallel data; and
powering off at least a portion of the phase-locked loop based clock recovery circuit outside the pre-defined burst cycles.

9. The method of claim 8, wherein a length of an interval between two adjacent burst cycles is variable.

10. The method of claim 8, wherein a duration of each burst cycle is a pre-defined fixed value.

11. The method of claim 8, wherein a duration of each burst cycle can be changed based on the size of payload data.

12. The method of claim 8, wherein the phase-locked loop comprises two loops running at different frequencies, with a low frequency loop always running and a high frequency loop running only during the pre-defined burst cycles.

13. The method of claim 8, wherein the phase-locked loop comprises a single loop which is only powered up during pre-defined burst cycles.

14. An apparatus to transmit data to a receiving device, comprising:
a phase-locked loop based clock synthesizer to generate a clock signal;
a serializer to convert parallel data to serialized data;
a transmitter to transmit the serialized data only during pre-defined burst cycles; and
a switch to power off at least a portion of the phase-locked loop based clock synthesizer outside the pre-defined burst cycles.

15. The apparatus of claim 14, wherein a length of an interval between two adjacent burst cycles is variable.

16. The apparatus of claim 14, wherein a duration of each burst cycle is a pre-defined fixed value.

17. The apparatus of claim 14, wherein a duration of each burst cycle can be changed based on the size of payload data.

18. The apparatus of claim 14, wherein the phase-locked loop comprises two loops running at different frequencies, with a low frequency loop always running a high frequency loop running only during the pre-defined burst cycles.

19. The apparatus of claim 14, wherein the phase-locked loop comprises a single loop which is only powered up during the pre-defined burst cycles.

20. An apparatus for receiving data from a serial link, comprising:
a phase-locked loop based clock recovery circuit for recovering a clock signal from a serial data input;
a sampling circuit for sampling serial data received at the input using the recovered clock signal;
a deserializer for converting the sampled serial data to paralleled data; and
a switch to power off at least a portion of the phase-locked off based clock recovery circuit outside the pre-defined burst cycles.

21. The apparatus of claim 20, wherein a length of an interval between two adjacent burst cycles is variable.

22. The apparatus of claim 20, wherein a duration of each burst cycle is a pre-defined fixed value.

23. The apparatus of claim 20, wherein a duration of each burst cycle can be changed based on the size of payload data.

24. The apparatus of claim 20, wherein the phase-locked loop comprises two loops running at different frequencies, with a low frequency loop always running and a high frequency running only during pre-defined burst cycles.

25. The apparatus of claim 20, wherein the phase-locked loop comprises a single loop which is only powered up during pre-defined burst cycles.

26. A device, comprising:
a first component and a second component;
a serial link connecting the first component and the second component;
wherein the first component transmits data to the second component only during pre-defined burst cycles.

27. The device of claim 26, further comprising:
a phase-locked loop based clock synthesizer for generating a clock signal;
a serializer for converting parallel data to serial data;
a transmitter transmitting the serial data only during the pre-defined burst cycles;
a switch to power off at least a portion of the phase-locked loop based clock synthesizer outside the pre-defined burst cycles;
a phase-locked loop based clock recovery circuit for recovering a clock signal from a serial data input;
a sampling circuit for sampling the serial data using the recovered clock signal;
a deserializer for converting the sampled serial data to paralleled data and
a switch to power off at least a portion of the phase-locked loop based clock recovery circuit outside the pre-defined burst cycles.

28. The device of claim 27, wherein a length of an interval between two adjacent burst cycles is variable.

29. The device of claim 27, wherein a duration of each burst cycle is a pre-defined fixed value.

30. The device of claim 27, wherein a duration of each burst cycle can be changed based on the size of payload data.

31. The device of claim 27, wherein a phase-locked loop used in clock generation and clock recovery circuit comprises two loops running at different frequencies, with a low frequency loop always running and a high frequency running only during pre-defined burst cycles.

32. The device of claim 27, wherein the phase-locked loop used in clock generation and clock recovery circuit comprises a single loop which is only powered up during the pre-defined burst cycle.

33. A device, comprising:
a first component and a second component;
a serial link connecting the first component and the second component;
a transmitter configured to transmit serial data from the first component only during pre-defined burst cycles;
a phase-locked loop based clock recovery circuit for recovering a clock signal from the serial link;
a sampling circuit for sampling the serial data input using the recovered clock signal;
a deserializer for converting the sampled serial data to paralleled data;
means for powering off at least a portion of the phase-locked loop based circuit; and
means for locking the phase and frequency of the phase-locked loop to that of the received data.

34. A chipset, comprising:
a phase-locked loop based clock synthesizer circuit to generate a clock signal;
a serializer circuit to convert parallel data to serial data;
a transmitter circuit to transmit the serial data only during pre-defined burst cycles;
a switch to power off at least a portion of the phase-locked loop based clock synthesizer outside the pre-defined burst cycles;
a phase-locked loop based clock recovery circuit to recover a clock signal from a serial data input;
a sampling circuit to sample the serial data input using the recovered clock signal;
a deserializer circuit to convert the sampled serial data to paralleled data; and
a switch to power off the phase-locked loop based clock recovery circuit outside the pre-defined burst cycles.
